(19) United States
(12) Patent Application Publication
(10) Pub. No.: US 2012/0305301 A1
(43) Pub. Date: Dec. 6, 2012

(54) CIRCUIT BOARD WITH HEAT SINK AND METHOD OF FABRICATING THE SAME

(75) Inventor: King-Lien Lee, Taipei (TW)

(73) Assignee: NATIONAL TAIPEI UNIVERSITY OF TECHNOLOGY, Taipei (TW)

(21) Appl. No.: 13/399,101

(22) Filed: Feb. 17, 2012

(30) Foreign Application Priority Data
Jun. 2, 2011 (TW) 100119340

(51) Int. Cl. H05K 1/02; H05K 3/00

(52) U.S. Cl. 174/258; 427/98.4

(57) ABSTRACT

The invention provides a circuit board with heat sink and a method of fabricating the same. The circuit board according to the invention includes a substrate, a lead layer and a ceramic layer. The lead layer is formed on an upper surface of the substrate, and includes two contact points corresponding to an electronic device. The ceramic layer is formed on the upper surface of the substrate, and particularly formed between such two contact points. The ceramic layer serves as a heat sink for the electronic device.

### CROSS-REFERENCE TO RELATED APPLICATION

This utility application claims priority to Taiwan Application Serial Number 100119340, filed Jun. 2, 2011, which is incorporated herein by reference.

### BACKGROUND OF THE INVENTION

1. Field of the Invention

The invention relates to a circuit board, and more particularly to a circuit board with a heat sink.

2. Description of the Prior Art

Most of electronic devices would generate heat during operation. If without well heat-conducting and heat-dissipating mechanism, these electronic devices will decrease performance thereof as temperature increasing, even reduce lifetime. Taking light-emitting diodes (LED) as an example, the luminescence efficiency of LEDs has already been improved to above 30 lm/W at present, it is expected in the future that can improve to above 120 lm/W. The heat dissipation problem of LEDs becomes more serious as the luminescence efficiency of LEDs increases. The junction temperature of LEDs rises as electric current increases. Over-high junction temperature will reduce output efficiency and lifetime of the LEDs.

A conventional printed circuit board whose substrate is formed from glass fibers, that is so-called FR4 printed circuit board, has thermal conductivity of about 0.36 W/mK. As to LEDs, FR4 glass substrate is only suitable for LEDs of low power.

As to electronic devices generating much heat during operation, such as LEDs of high power, there have been circuit boards using metal with high thermal conductivity, such as aluminum, copper etc., as substrates, which are so-called metal-core printed circuit boards (MCPCB). Because the metal substrate used in the MCPCB is well conductor, an insulator must be used to electrically insulate the metal substrate and the lead layer of the MCPCB to prevent from conduction forming between the metal substrate and the lead layer. However, most of the MCPCBs have insulating layers formed of polymer which have thermal conductivity of only about 0.2˜0.5 W/mK and poor thermal endurance. Therefore, the insulating layer of polymer is introduced into the MCPCB, which originally uses the metal substrate of well thermal conductivity, to form a thermal barrier for the MCPCB to significantly reduce heat-conducting efficiency of whole MCPCB such that the thermal conductivity of the MCPCB is only 1˜2.2 W/mK.

There have been circuit boards using well thermally conductive and insulating ceramic substrates, formed of AlN, Al₂O₃ and so on, and lead layers formed on the ceramic substrates. The ceramic substrates used in circuit boards are generally classified into high-temperature co-fired ceramic (HTCC) substrates, low-temperature co-fired ceramic (LTCC) substrates, direct bonded copper (DBC) substrates and direct plate copper (DPC) substrates, haves thermal conductivity of 2˜220 W/mK according to their processes. The cost of the circuit board using ceramic substrate is still high.

With description above for the prior arts of circuit boards, it is clearly understood that there is a need for a new circuit board structure to satisfy requirements of well heat dissipation and low manufacture cost for circuit boards.

### SUMMARY OF THE INVENTION

Accordingly, a scope of the invention is to provide a circuit board with a heat sink. Moreover, in particular, the circuit board according to the invention is distinguishable from the circuit board of the prior art, and has excellent heat-dissipation performance and low manufacture cost.

A circuit board, according to a preferred embodiment of the invention, includes a substrate, a lead layer and a ceramic layer. The lead layer is formed on an upper surface of the substrate, and includes two contact points corresponding to an electronic device. The ceramic layer is formed on the upper surface of the substrate and between such two contact points. In particular, the ceramic layer serves as a heat sink for the electronic device.

In one embodiment, the electronic device includes a die, and the width of the die is less than that of the ceramic layer.

In one embodiment, the thickness of the ceramic layer is about equal to that of the lead layer.

In one embodiment, the ceramic layer can be formed of Al₂O₃, AlN, SiC, SiO₂, BeO, Si₃N₄, or other ceramic with well heat conduction and well insulation.

In another preferred embodiment of the invention, the ceramic layer is formed into a strip-like ceramic layer which extends to a side and a lower surface of the substrate.

A method of fabricating a circuit board according to a preferred embodiment of the invention, firstly, is to prepare a substrate. Then, the method is to form a lead layer on an upper surface of the substrate. The lead layer includes two contact points corresponding to an electronic device. Finally, the method is to form a ceramic layer on the upper surface of the substrate and between such two contact points. The ceramic layer serves as a heat sink for the electronic device.

In one embodiment, the ceramic layer is formed by firstly forming a layer of a material on the upper surface of the substrate and between such two contact points. The layer of the material can be formed of Al, Si, Be and so on. Then, the layer of the material is exposed at a high temperature oxygen or vapor atmosphere such that the layer of the material is oxidized into the ceramic layer.

In one embodiment, the ceramic layer can be formed by metal-organic chemical vapor deposition (MOCVD) process, an RF sputtering process, a molecular beam epitaxy (MBE) process, an atomic layer deposition (ALD) process, etc.

Compared to the prior arts of the circuit boards, the circuit board according to the invention has advantages of well heat-dissipation performance, low-cost manufacture, etc.

The advantage and spirit of the invention may be understood by the following recitations together with the appended drawings.

### BRIEF DESCRIPTION OF THE APPENDED DRAWINGS

FIG. 1 is an outside perspective view of a circuit board according to a preferred embodiment of the invention.

FIG. 2 is a sectional view of the circuit board along A-A line in FIG. 1.

FIG. 3 is an outside perspective view of a circuit board according to another preferred embodiment of the invention.

FIG. 4 is a sectional view of the circuit board along B-B line in FIG. 3.

FIGS. 5A through 5C illustratively show sectional views of a method according to a preferred embodiment of the invention to fabricate the circuit board as shown in FIG. 2.

### DETAILED DESCRIPTION OF THE INVENTION

The invention provides a circuit board with a heat sink. Moreover, in particular, the circuit board according to the invention is distinguishable from the circuit board of the prior art, and has excellent heat-dissipation performance and low manufacture cost. Some preferred embodiments of this present invention would be explained in the following paragraph, describing the characteristics, spirit, advantages of the invention, and feasibility of embodiment.

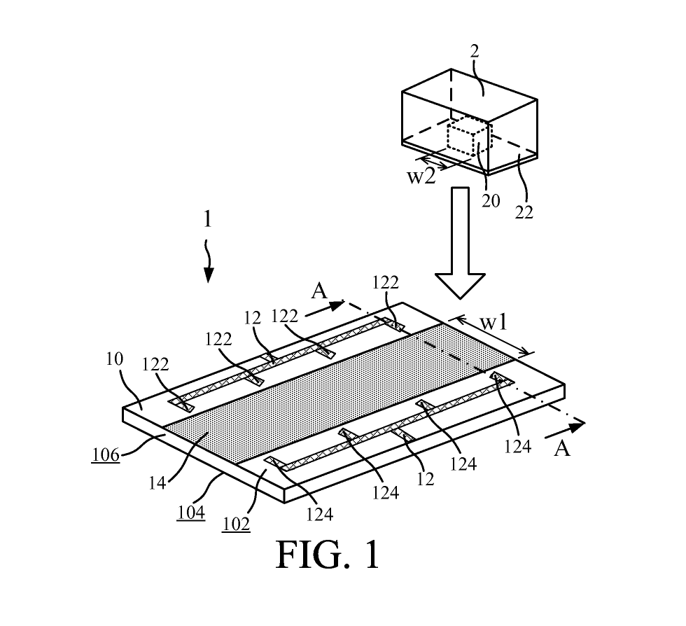

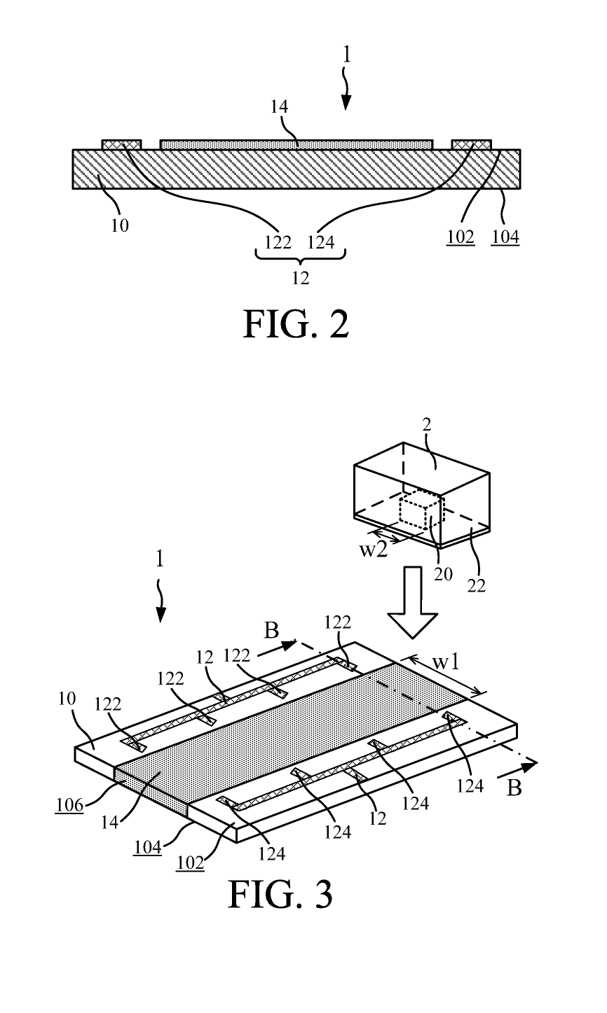

Referring to FIG. 1 and FIG. 2, FIG. 1 is an outside perspective view of a circuit 1 according to a preferred embodiment of the invention. FIG. 2 is a sectional view of the circuit board 1 along A-A line in FIG. 1. An electronic device 1 capable of being soldered on the circuit board 1 is also illustrated in FIG. 1 to benefit in description.

As shown in FIG. 1 and FIG. 2, the circuit board 1 according to the invention includes a substrate 10, a lead layer 12 and a ceramic layer 14. The lead layer 12 is formed on an upper surface 102 of the substrate 12, and includes two contact points (122, 124) corresponding to the electronic device 2. Similar to a typical circuit board, the lead layer 2 formed on the circuit board 1 according to the invention provides a plurality of electronic devices 2 with bonding. Although in order to describe conveniently, FIG. 1 only illustrates one electronic device 2, the lead layer 12 in FIG. 1 illustrates four sets of contact points (122, 124) to show bonding for the corresponding electronic devices 2.

In practical application, the substrate 10 can be an FR4 glass substrate. The led layer 12 can be a copper foil layer.

Also shown in FIG. 1 and FIG. 2, the ceramic layer 14 is formed on the upper surface 102 of the substrate 10 and between such two contact points (122, 124). It is noted that the ceramic layer 14 serves as a heat sink for the electronic device 2.

In one embodiment, as shown in FIG. 1, the electronic device 2 includes a die 20 and a package substrate 22. The die is bonded on the package substrate 20. Moreover, the width w2 of the die 20 is less than the width w1 of the ceramic layer 14. That is to say, the width w1 of the ceramic layer 14 serving as the heat sink is wider enough to cover the die 20 to achieve significant heat dissipation performance. The width w1 of the ceramic layer 14 is at most equal to the distance between such contact points (122, 124).

In practical application, the electronic device 2 can be, but not limited to, an SMT (surface mounting technology) or a DIP (dual in-line package) device.

In one embodiment, the thickness of the ceramic layer 14 is about equal to that of the lead layer 12. That is to say, the thickness of the ceramic layer 14 is thick enough so that the bottom of the electronic device 2 bonded on the substrate 10 can preferredly urge against the ceramic layer 14. In general, the lead layer 12 has a thickness of about 35˜175 μm. Therefore, in practical application, the thickness of the ceramic layer 14 is about 35˜175 μm.

In one embodiment, the ceramic layer 14 can be formed of Al₂O₃, AlN, SiC, SiO₂, BeO, Si₃N₄, or other ceramic with well heat conduction and well insulation.

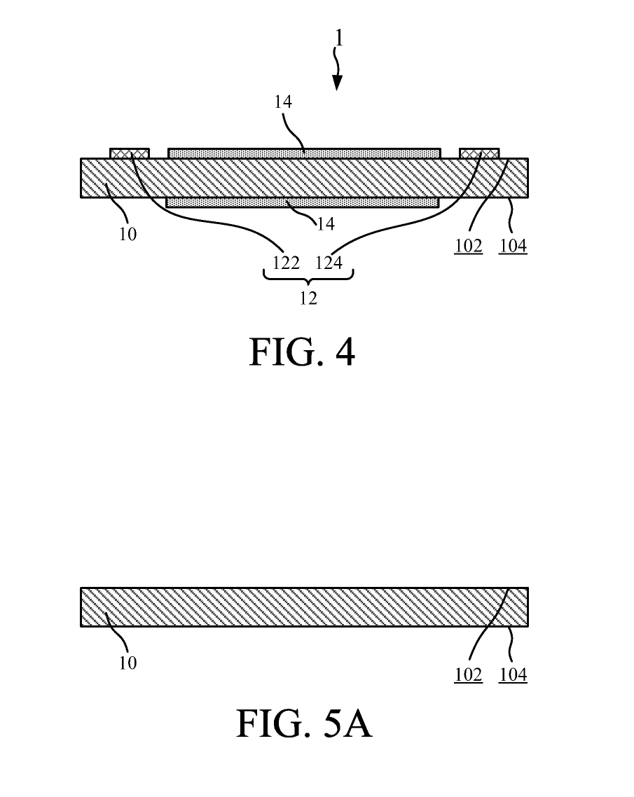

Referring to FIG. 3 ad FIG. 4, FIG. 3 is an outside perspective view of a circuit board 1 according to another preferred embodiment of the invention. FIG. 4 is a sectional view of the circuit board 1 along B-B line in FIG. 4. The circuit board 1 shown in FIG. 3 and FIG. 4 has the architecture similar to that of the circuit board 1 shown in FIG. 1 and FIG. 2. The components in FIG. 3 and FIG. 4 with the same numbers as those in FIG. 1 and FIG. 2 have the same or similar function or operation, and the related description will not be mentioned again here. Hereinafter only explains the difference between the circuit board 1 shown in FIG. 3 and FIG. 4 and the circuit board 1 shown FIG. 1 and FIG. 2.

As shown in FIG. 3 and FIG. 4, in the circuit board 1 according to another preferred embodiment of the invention, the ceramic layer 14 is formed into a strip-like ceramic layer 14 which extends to a side 106 and a lower surface 104 of the substrate 10 to benefit in enhancing heat storage capacity of the ceramic layer 14 serving as the heat sink.

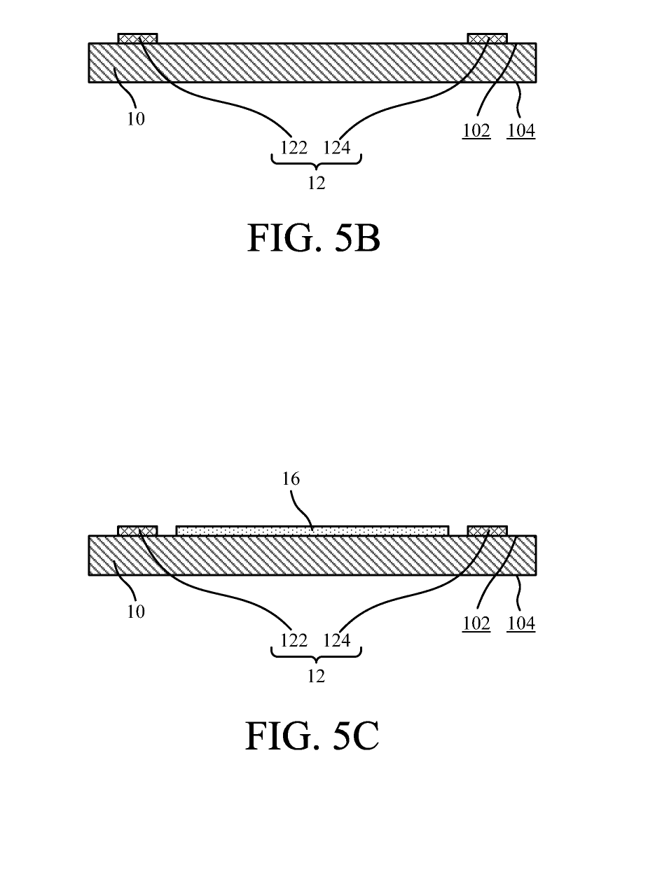

Referring to FIGS. 5A through 5C and FIG. 2, these figures illustratively show sectional views of a method according to a preferred embodiment of the invention to fabricate the circuit board as shown in FIG. 2.

As shown in FIG. 5A, the method according to the invention, firstly, is to prepare a substrate 10. The substrate 10 has an upper surface 102 and a lower surface 104.

Then, as shown in FIG. 5B, the method according to the invention is to form a lead layer 14 such a copper foil layer 14 on the upper surface 102 of the substrate 10. It is noted that the lead layer 14 includes two contact points (122, 124) corresponding to the electronic device 2 for example as shown in FIG. 1.

Finally, the method according to the invention is to form a ceramic layer 14 on the upper surface 102 of the substrate 10 and between such two contact points (122, 124). The ceramic layer 14 serves as a heat sink for the electronic device 2 for example as shown in FIG. 1.

Regarding formation of the ceramic layer 14, as shown in FIG. 5C, a method is, firstly, to form a layer of a material 16 on the upper surface 102 of the substrate 10 and between such two contact points (122, 124). The layer of the material 16 can be formed of Al, Si, Be and so on. Then, the layer of the material 16 is exposed at a high temperature oxygen or vapor atmosphere such that the layer of the material 16 is oxidized into the ceramic layer 14. During oxidization of the layer of the material 16, other portion of the substrate 10 other than the layer of the material 16 is masked to prevent from being oxidized. Obviously, compared to prior arts of making circuit boards using ceramic substrates, the method of fabricating the circuit board with the heat sink according to the invention has low-cost manufacture.

Additionally, in one embodiment, the ceramic layer 14 can also be formed, by an MOCVD process, an RF sputtering process, an MBE process, an ALD process and so on, on the upper surface 102 of the substrate 10 and between such two contact points (122, 124). The processes all are commercialized processes, and use to form the ceramic layer on the substrate in part. Therefore, compared to the prior arts of making circuit boards using ceramic substrates, the method of fabricating the circuit board with the heat sink according to the invention has low-cost manufacture.

An example uses LEDs as the electronic devices and a circuit board with a heat sink according to the invention, and conducts a thermal simulation analysis. Data relative to the LED are listed in table 1. The substrate according to the invention is a 60 mm×60 mm×1.5 mm FR4 substrate which contains 30% glass fibers and has thermal conductivity of 1 W/mK. 16 LEDs are arranged on the substrate in a form of array, and pass a current of 0.5 W to achieve total passing-through power of 8 W. The lead layer formed of copper has a thickness of 0.070 mm. The ceramic layer serving as the heat sink has a length of 62 mm, a width of 7 mm and a thickness of 0.070 mm.

In this case, the thermal simulation analysis software employs FLOTHERM to perform test of heat dissipation. The thermal simulation analysis performs by analyzing at (a) interiors of the 16 LEDs, (b) interfaces between the LEDs and the heat sink, and (c) interfaces between the heat sink and the substrate, and under conditions of without heat sink, with FR4 heat sink, with Al₂O₃ heat sink, with AlN heat sink and with Cu heat sink.

As to the condition of without heat sink, the result of thermal simulation analysis presents that temperature of the simulated system mainly concentrates at the interiors of the LEDs, the highest average temperature is close to 94.90° C., heat is mainly dissipated by Cu lead layer, the temperature at the interface between the heat sink and the substrate is 79.61° C., relative thermal resistance is about 0.956° C./W, and total thermal resistance is about 4.369° C./W.

TABLE 1
package substrate

| | |
|---|---|
| length: | 7.4 mm |
| width: | 11.1 mm |
| height: | 0.035 mm |

die

| | |
|---|---|
| length: | 2.8 mm |
| width: | 3.2 mm |
| thickness (upper layer): | 0.95 mm |
| thickness (lower layer): | 0.95 mm |
| thermal resistance of upper layer: | 1 × 10¹⁰ K/W (heat cannot penetrate |
| | through) |
| thermal resistance of lower layer: | 11 K/W |
| thermal conductivity: | 395 W/mK |

As to the condition of with FR4 heat sink, the result of thermal simulation analysis presents that temperature of the simulated system mainly concentrates at the interiors of the LEDs, the highest average temperature is close to 91.27° C., heat is mainly dissipated by Cu lead layer and slightly dissipated by the substrate, the temperature at the interface between the heat sink and the substrate is 68.55° C., relative thermal resistance is about 1.420° C./W, and total thermal resistance is about 4.142° C./W.

As to the condition of with Al₂O₃ heat sink, the result of thermal simulation analysis presents that temperature of the simulated system mainly concentrates at the interiors of the LEDs, the highest average temperature is close to 57.85° C., heat is mainly dissipated by Cu lead layer and the heat sink, the temperature at the interface between the heat sink and the substrate is 57.11° C., relative thermal resistance is about 0.046° C./W, and total thermal resistance is about 2.053° C./W.

As to the condition of with A1N heat sink, the result of thermal simulation analysis presents that temperature of the simulated system mainly concentrates at the interiors of the LEDs, the highest average temperature is close to 57.00° C., heat is mainly dissipated by Cu lead layer and the heat sink, the temperature at the interface between the heat sink and the substrate is 56.88° C., relative thermal resistance is about 0.020° C./W, and total thermal resistance is about 2.000° C./W.

As to the condition of with Cu heat sink, the result of thermal simulation analysis presents that temperature of the simulated system mainly concentrates at the interiors of the LEDs, the highest average temperature is close to 56.90° C., heat is mainly dissipated by Cu lead layer and the heat sink, the temperature at the interface between the heat sink and the substrate is 56.61° C., relative thermal resistance is about 0.018° C./W, and total thermal resistance is about 1.994° C./W.

With comparison among the thermal simulation analysis results under conditions of without heat sink, with FR4 heat sink, with Al₂O₃ heat sink, with AlN heat sink and with Cu heat sink, the highest average temperatures are 94.90° C., 91.27° C., 57.85° C., 57.00° C., and 56.90° C. respectively. The results of thermal simulation analysis can prove that Al₂O₃ heat sink, AlN heat sink and Cu heat sink all effectively dissipate heat for electronic devices. But it must be considered that the lead layer cannot have short circuit, so the heat sink is preferredly formed of ceramic. With above explanation for the invention, it is clearly understood that the circuit board with the heat sink according to the invention is distinguishable from the circuit board of the prior art, and has excellent heat-dissipation performance and low manufacture cost.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A circuit board, comprising:
a substrate;
a lead layer, being formed on an upper surface of the substrate, and comprising two contact points corresponding to an electronic device; and
a ceramic layer, formed on the upper surface of the substrate and between said two contact points, wherein the ceramic layer serves as a heat sink for the electronic device.

2. The circuit board of claim 1, wherein the electronic device comprises a die, the width of the die is less than that of the ceramic layer.

3. The circuit board of claim 2, wherein the thickness of the ceramic layer is about equal to that of the lead layer.

4. The circuit board of claim 2, wherein the ceramic layer is formed into a strip-like ceramic layer which extends to a side and a lower surface of the substrate.

5. The circuit board of claim 2, wherein the ceramic layer is formed of one selected from the group consisting of Al₂O₃, AlN, SiC, SiO₂, BeO and Si₃N₄.

6. A method of fabricating a circuit board, comprising the steps of:
preparing a substrate;
forming a lead layer on an upper surface of the substrate, wherein the lead layer comprises two contact points corresponding to an electronic device; and
forming a ceramic layer on the upper surface of the substrate and between said two contact points, wherein the ceramic layer serves as a heat sink for the electronic device.

7. The method of claim 6, wherein the electronic device comprises a die, the width of the die is less than that of the ceramic layer.

8. The method of claim 7, wherein the thickness of the ceramic layer is about equal to that of the lead layer.

9. The method of claim 7, wherein the ceramic layer is formed by the steps of:
forming a layer of a material between said two contact points, wherein the material is selected from the group consisting of Al, Si and Be; and
exposing the layer of the material at a high temperature oxygen or vapor atmosphere to oxide the layer of the material into the ceramic layer.

10. The method of claim 7, wherein the ceramic layer is formed of one selected from the group consisting of Al₂O₃, AlN, SiC, SiO₂, BeO and Si₃N₄, and the ceramic layer is formed by one selected from the group consisting of an MOCVD process, an RF sputtering process, an MBE process, a PLD process and an ALD process.
